(19) United States
(12) Patent Application Publication
(10) Pub. No.: US 2012/0196422 A1
(43) Pub. Date: Aug. 2, 2012

(54) Stress Memorization Technique Using Gate Encapsulation

(75) Inventors: Stefan Flachowsky, Dresden (DE); Jan Hoentschel, Dresden (DE); Thilo Scheiper, Dresden (DE)

(73) Assignee: GLOBALFOUNDRIES INC., Grand Cayman (KY)

(21) Appl. No.: 13/015,329

(22) Filed: Jan. 27, 2011

(51) Int. Cl. H01L 21/336; H01L 21/4763

(52) U.S. Cl. 438/305; 438/595; 257/E21.409; 257/E21.495

(57) ABSTRACT

Generally, the subject matter disclosed herein relates to sophisticated semiconductor devices and methods for forming the same, wherein a stress memorization technique is used to enhance the performance of MOS transistor elements. One illustrative embodiment includes a method for forming a gate electrode above a channel region of a semiconductor device, wherein the channel region is formed in an active region of a semiconductor substrate. The method further includes forming a dielectric encapsulating layer in direct contact with the gate electrode, and performing a heat treatment process to induce a residual stress in the channel region.

### BACKGROUND

1. Field of the Disclosure

Generally, the present disclosure relates to sophisticated integrated circuits, and, more particularly, to utilizing a stress memorization technique to enhance the performance of semiconductor devices such as transistor elements and the like.

2. Description of the Related Art

In modern ultra-high density integrated circuits, device features have been steadily decreasing in size to enhance the performance of the semiconductor device and the overall functionality of the circuit. In addition to an increase in the speed of operation due to reduced signal propagation times, reduced feature sizes allow an increase in the number of functional elements in the circuit in order to extend its functionality. Today, advanced semiconductor devices may include features having a critical size of 45 nm or even less.

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, CMOS technology is currently the most promising approach, due to the superior characteristics in view of operating speed and/or power consumption. During the fabrication of complex integrated circuits using CMOS technology, millions of complementary transistors, i.e., N-channel (NMOS) transistors and P-channel (PMOS) transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source region. The conductivity of the channel region, i.e., the drive current capability of the conductive channel, is controlled by a gate electrode formed above the channel region and separated from the channel by a thin gate insulating layer, or gate dielectric. In operation, an appropriate control voltage is applied to the gate electrode, which thereby forms a conductive channel below the gate electrode. The conductivity of the channel region depends on several factors, including dopant concentration, the mobility of the charge carriers, and, for a given extension of the channel region in the transistor width direction, on the distance between the source and drain regions, which is also referred to as channel length. Therefore, in combination with the capability of rapidly creating a conductive channel below the insulating layer upon application of the control voltage to the gate electrode, the conductivity of the channel region substantially determines the performance of the MOS transistors. Thus, the reduction of the channel length, and the commensurate reduction of the channel resistivity, renders the channel length a dominant design criteria for accomplishing an increase in the operating speed of the integrated circuits.

The shrinkage of the transistor dimensions, however, carries with it a plurality of issues which have to be addressed so as to not unduly offset the advantages that may be obtained by steadily decreasing the channel length of MOS transistors. One major problem in this respect is the development of enhanced photolithography and etch strategies to reliably and reproducibly create circuit elements having very small critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability. In addition, the vertical location of the PN junctions with respect to the gate insulation layer also represents a critical design criterion in view of leakage current control. As a general rule, reducing the channel length also requires reducing the depth of the drain and source regions with respect to the interface formed by the gate insulation layer and the channel region, thereby requiring sophisticated implantation techniques. According to other approaches, epitaxially grown regions are formed with a specified offset to the gate electrode, which are referred to as raised drain and source regions, to provide increased conductivity of the raised drain and source regions, while at the same time maintaining a shallow PN junction with respect to the gate insulation layer.

Irrespective of the technological approach used, sophisticated spacer techniques are typically employed to create the highly complex dopant profile and to serve as a mask in forming metal silicide regions in the gate electrode and the drain and source regions in a self-aligned fashion. Given the continuous size reduction of the critical dimensions, i.e., the gate length of the transistors, it has been proposed to also enhance device performance of the transistor elements by increasing the charge carrier mobility in the channel region for a given channel length. In principle, at least two mechanisms may be used, in combination or separately, to increase the mobility of the charge carriers in the channel region. First, the dopant concentration within the channel region may be reduced, thereby reducing scattering events for the charge carriers and thus increasing the conductivity. However, reducing the dopant concentration in the channel region significantly affects the threshold voltage of the transistor device, thereby making a reduction of the dopant concentration a less attractive approach unless other mechanisms are developed to adjust a desired threshold voltage. Second, the lattice structure in the channel region may be modified, for instance by creating tensile or compressive stress, which results in a modified mobility for electrons and holes. For example, creating tensile stress in the channel region increases the mobility of electrons, wherein, depending on the magnitude of the tensile stress, an increase in mobility of up to 20% may be obtained, which, in turn, may directly translate into an increased channel conductivity and a corresponding improvement in NMOS transistor performance. On the other hand, compressive stress in the channel region may increase the mobility of holes, thereby providing the potential for enhancing the performance of P-type transistors.

Currently, several different methods are used, either alone or in combination, to induce an appropriate type of stress in the channel region of MOS transistors so as to enhance overall device performance. For example, in some devices, a material layer having an intrinsic internal stress—i.e., a stressed overlayer—may be formed above the transistor elements, wherein the intrinsic stress of the overlayer is transferred through the gate electrode and any sidewall spacer elements to the channel region below the gate insulating layer. The stressed overlayer method, however, has some inherent drawbacks. For example, once formed, the stressed overlayer must generally remain in place throughout all remaining process steps, so that the beneficial stress imparted to the channel region by the stressed overlay is maintained in the final device configuration. Additionally, the presence of any intermediate device elements or material layers between the stressed overlayer and the targeted channel region of a MOS transistor—such as the aforementioned sidewall spacer elements—may tend to mitigate the level of stress than can be transferred through those elements or layers to the channel. Furthermore, specific deposition parameters are necessary when forming the stressed overlayer, depending on the type and degree of desired stress. Moreover, the deposition of a stressed overlayer adds level of process complexity to the overall process flow used for forming the MOS transistors.

Another method used for introducing a stress into the channel region of MOS transistors involves forming a separate material layer in the active area of the transistor adjacent to the channel region so as to induce a tensile or compressive stress field in the channel. For example, a silicon/germanium material layer or a silicon/carbon material layer may be formed in or below the channel region to create the appropriate type and level of stress. For instance, additional epitaxial growth techniques may be implemented into the overall process flow to form the stressed germanium or carbon-containing silicon material layers at appropriate locations in or below the channel region. However, although the transistor performance may be enhanced by the introduction of stress-creating layers in or below the channel region, process complexity is significantly increased, thereby also increasing production costs and the potential for a reduction in production yield.

Yet another method for obtaining a stress field in the channel region of MOS transistors is the so-called stress memorization technique. FIGS. 1a-1e depict one illustrative prior art method of utilizing a stress memorization technique to enhance device performance of an illustrative NMOS transistor, as will be described in detail below.

FIG. 1a schematically shows a cross-sectional view of an illustrative semiconductor device 100 comprising a substrate 101, in and above which an illustrative NMOS transistor element 150N may be formed. The illustrative NMOS transistor element 150N may include a gate electrode structure 111, and the substrate 101 may represent any appropriate substrate on which may be formed a semiconductor layer 103, such as a silicon-based layer, or any other appropriate semiconductor material that facilitates the formation of the illustrative NMOS transistor element 150N. It should be appreciated that the semiconductor layer 103, even if provided as a silicon-based layer, may include other materials, such as germanium, carbon and the like, in addition to an appropriate P-type dopant species, such as boron and the like, for establishing the requisite conductivity type in an active region 102 of the semiconductor layer 103. Furthermore, in some illustrative embodiments, transistor element 150N may be formed as one of a plurality of bulk transistors, i.e., the semiconductor layer 103 may be formed on or be part of a substantially crystalline substrate material, while in other cases specific device regions of the device 100 or the entire device 100 may be formed on the basis of a silicon-on-insulator (SOI) architecture, in which a buried insulating layer (not shown) may be provided below the semiconductor layer 103.

As shown in FIG. 1a, the active region 102 is typically enclosed by an isolation structure 104, which in the present example may be provided in the form of a shallow trench isolation that is typically used for sophisticated integrated circuits. In the illustrated embodiment, highly doped source and drain regions 106, including extension regions 105 that usually comprise a dopant concentration less than the highly doped regions 106, are formed in the active region 102. The source and drain regions 106, including the extension regions 105, are laterally separated by a channel region 107. The gate electrode structure 111 is formed above the channel region 107 and may be made up of a gate insulation layer 108, which electrically and physically isolates a gate electrode 109 from the underlying channel region 107. Furthermore, as shown in FIG. 1a, sidewall spacer structures 110 are formed on sidewalls of the gate electrode 109. Depending on the device requirements and/or the process strategy, the sidewall spacer structures 110 may include two or even more spacer elements, such as offset spacers, conformal liners, and the like. FIG. 1a depicts one illustrative embodiment, wherein the sidewall spacer structures 110 may be made up of a conformal liner or spacer 110a, and a spacer element 110b.

The semiconductor device 100 as shown in FIG. 1a may be formed on the basis of well-established process techniques. First, the trench isolation structure 104 may be formed utilizing patterning, etching, deposition, and/or planarizing techniques that are well known to those of ordinary skill in the art. Thereafter, the gate electrode structure 111 may be formed on the basis of sophisticated deposition and/or oxidation techniques for forming the gate dielectric material 108, wherein an appropriate thickness and material type, such as silicon dioxide, silicon oxynitride, and the like may be selected depending on device requirements. Next, the material of the gate electrode 109, which in some illustrative embodiments may comprise polysilicon, is deposited above the gate dielectric material, followed by sophisticated lithography and anisotropic etch techniques to obtain a desired gate length, which is the horizontal extension of the gate electrode 109 in FIG. 1a, i.e., in the plane of the drawing of FIG. 1a.

In some embodiments, the gate electrode structure 111 may comprise a so-called “high-k metal gate” (HK/MG) configuration, wherein the gate dielectric material 108 is a material having a dielectric constant of approximately 10 or greater. For example, the high-k gate dielectric material 108 may include materials such as tantalum oxide (Ta₂O₅), strontium titanium oxide (SrTiO₃), hafnium oxide (HfO₂), hafnium silicon oxide (HfSiO), zirconium oxide (ZrO₂) and the like. Furthermore, when the gate electrode structure 111 comprises an HK/MG configuration, the gate electrode 109 may comprise an appropriate metal gate material, such titanium nitride (TiN), titanium aluminum nitride (TiAlN), titanium silicon nitride (TiSiN) and the like. In some embodiments, the gate electrode 109 may comprise multiple layers, e.g., a first layer 109a of metal gate material formed above the high-k gate dielectric material 108, with a second layer 109b of polysilicon material, as described above. However, as will later be discussed in greater detail, the presence of a metal gate material in the gate electrode 109 may have a diminishing effect on the level of stress that may be induced in the channel region 107 of the illustrative NMOS transistor 150N using the stress memorization technique described below.

Next, the sidewall spacer structures 110 may be formed, at least partially, so as to act as an appropriate implantation mask for creating the lateral dopant profile for the drain and source regions 106 and extension regions 105. In the illustrated embodiment of FIG. 1a, the conformal liner or spacer 110a may be formed to exhibit a substantially L-shaped configuration. That is, the conformal spacer 110a may comprise a portion of a specified thickness that extends along the sidewall of the gate electrode 109 and may also comprise a portion having substantially the same thickness that extends horizontally along a part of the active region 102 in which the source/drain and extension regions 106, 105 are to be formed. Consequently, the conformal spacer 110a may have a shape which substantially corresponds to the shape of the gate electrode 109, with a “horizontal” portion extending along a part of the drain and source regions 106, thereby separating one or more additional spacer elements 110b from the gate electrode 109 and the source/drain and extension regions 106, 105.

As shown in FIG. 1a, the sidewall spacer structures 110 may further comprise a sidewall spacer element 110b which may be formed using well known techniques. For example, in some illustrative embodiments, sidewall spacer element 110b may be formed of a dielectric material that may exhibit a significant etch selectivity with respect to the dielectric material of the conformal spacer 110a in view of a specific etch recipe so as to enable a selective removal of the spacer element 110b while substantially maintaining the conformal spacer 110a. For example, in one illustrative embodiment, the conformal or L-shaped spacer 110a may be comprised of silicon dioxide, while spacer element 110a may be comprised of silicon nitride. However, other regimes for the spacer elements 110a and 110b may be contemplated. For instance, in another illustrative embodiment, the L-shaped spacer 110a may be comprised of silicon nitride, while the spacer element 110a may be formed of silicon dioxide. Depending on the process strategy, there may or may not be a cap layer (not shown) formed on top of the gate electrode 109.

Prior to the deposition and/or removal of respective portions of the sidewall spacer structures 110, various implantation processes may be performed in order to obtain the required lateral dopant profile in the extension regions 105, and in the source/drain regions 106. It should be appreciated that a plurality of implantation processes may be required, such as pre-amorphization implantation, halo implantation, extension implantation and deep drain and source implantations for obtaining the required complex dopant profile. For example, halo implantation regions (not shown) may be formed using an appropriately designed ion implantation process to implant P-type dopants, such as boron and the like, whereas N-type dopants, such as phosphorous, arsenic, and the like, may be implanted to form the lightly doped extension regions 105, as well as the highly doped source/drain regions 106.

FIG. 1a further illustrates a deposition process 131, which is used to form a sacrificial silicon nitride encapsulating layer 112 above the semiconductor device 100. The deposition process 131 may be, for example, a suitably designed conformal deposition process, such as a low pressure chemical vapor deposition (LPCVD) process, an atomic layer deposition (ALD) process, a plasma enhanced chemical vapor deposition (PECVD) process, and the like. After deposition, the sacrificial silicon nitride encapsulating layer 112 therefore encloses the gate electrode structure 111 on three sides, i.e., adjacent the sidewall spacer structures 110 on each side of the gate electrode structure 111, as well as above the gate electrode 109.

FIG. 1b shows the semiconductor device 100 of FIG. 1a during a subsequently performed heat treatment process 132. Depending on the specific operating parameters, the heat treatment process 132 may induce a memorized stress in the channel region 107 of the illustrative NMOS transistor element 150N, as described below. Furthermore, the heat treatment process 132 may also serve to activate the N-type dopants previously implanted in the extension regions 105 and the source/drain regions 106, as discussed above. The specific time and temperature parameters of the heat treatment process 132 may depend on several device design considerations, such as, for example, the specific materials comprising the gate electrode 109, the semiconductor material 103, the type and level of stress desired for the channel region 107, and the like. For example, the heat treatment process 132 may be a rapid thermal anneal (RTA) process, and may be performed at approximately 1000°-1100° C. for approximately 2 seconds.

While the precise mechanisms associated with the stress memorization technique are not fully understood, it is generally believed that the following explanation best describes the phenomenon. During the heat treatment process 132, the material of the gate electrode 109 and the silicon nitride material comprising the sacrificial encapsulating layer 112 will each seek to expand in accordance with that material's normal thermal expansion properties. Therefore, the gate electrode 109 will typically try to expand (as indicated by arrows 120) more than the sacrificial silicon nitride material encapsulating 112 surrounding it. However, due to the higher hardness and greater material strength of the sacrificial silicon nitride encapsulating layer 112 relative to the gate electrode 109, and the fact that the higher strength encapsulating layer 112 effectively encloses the gate electrode structure 111 on three sides, the material comprising the gate electrode 109 may plastically deform during the heat treatment process 132. Furthermore, the material of the gate electrode 109 may be forced to expand in the only direction that it is relatively unconstrained—i.e., downward toward the gate dielectric layer 108/channel region 107 interface. Once the heat treatment temperature is reduced and the illustrative NMOS transistor element 150N is permitted to cool, the plastically deformed gate electrode material 109 substantially maintains its deformed shape, thereby inducing a stress in the channel region 107 below the gate dielectric layer 108. This induced stress may be made up of both a lateral (i.e., approximately parallel to the gate dielectric layer 108) tensile stress component 121, and a vertical (i.e., approximately perpendicular to the gate dielectric layer 108) compressive stress component 122. As discussed previously, the lateral tensile stress component 121 induced in the channel region 107 thereby increases the mobility of electrons of up to 20%, which, in turn, may directly translate into an increased channel conductivity and a corresponding improvement in NMOS transistor performance.

FIG. 1c illustrates the semiconductor device 100 of FIG. 1b after performing an etch process 133 to remove the sacrificial silicon nitride encapsulating layer 112. The etch process 133 may be, for example, an appropriately designed isotropic wet etch process selective to silicon nitride, such as a hot phosphoric acid etch, and the like. As shown in FIG. 1c, the stresses 121, 122 induced in the channel region 107 remain in place—i.e., the stress is “memorized”—even after to the overlying sacrificial silicon nitride material encapsulating layer 112 has been removed by the etch process 133.

It should be noted that the level of stress induced in the channel region 107 may be affected by presence of material layers and/or other transistor elements between the sacrificial silicon nitride encapsulating layer 112 and the gate electrode 109 during performance of the heat treatment process 132. For example, in the embodiment illustrated in FIGS. 1a-1b, the sidewall spacer structures 110 are disposed between the gate electrode 109 and the sacrificial silicon nitride encapsulating layer 112. So as to provide the requisite etch selectivity to the silicon nitride of the sacrificial encapsulating layer 112, the sidewall spacer structures may be comprised of, for example, silicon dioxide material. Since the silicon dioxide of the sidewall spacer structures 110 has a significantly lower hardness and strength than the silicon nitride of the sacrificial encapsulating layer 112 surrounding it, some deformation of the silicon dioxide material may occur during the heat treatment process 132, and the full benefits of the “encapsulating effect” of the sacrificial encapsulating layer 112 may not be realized. Moreover, in those embodiments where the gate electrode 109 comprises a metal gate material 109a as discussed above, the metal gate material 109a may in some cases, and depending on its material properties, act to constrain the expansion of the polysilicon material 109b, thereby further reducing the amount of stress that may be induced in the channel region 107 by the gate electrode 109 during the heat treatment process 132.

FIG. 1d shows the semiconductor device 100 of FIG. 1c after a refractory metal layer 113 comprising, for example, nickel or cobalt, and the like, has been deposited above the device 100. Thereafter, a heat treatment process 134 may be performed so as to form metal silicide contact regions 116, 117 in the source/drain regions 106 and the gate electrode 109, respectively, in accordance with recipes that are well known in the art. However, as is well known by those having ordinary skill in the art, metal silicide regions will only be formed in those areas where the refractory metal layer 113 is in direct contact with the silicon-containing materials of the active region 102 and/or the gate electrode 109. On the other hand, metal silicides will not form in those areas where in the refractory metal layer 113 is in contact with dielectric materials, such as, for example, the sidewall spacer structures 110 and/or the trench isolation regions 104. Furthermore, it should be appreciated that any residual portions of the sacrificial silicon nitride encapsulating layer 112 that might not be removed from above the source/drain regions 106 and the gate electrode 109 of the semiconductor device 100 during the etch process 133 may at least partially prevent silicide formation in those areas, thereby possibly leading to contact region defects and higher overall contact resistivity.

Therefore, the additional steps associated with: 1) depositing the sacrificial silicon nitride encapsulating layer 112; 2) performing the heat treatment process 132 to induce a memorized stress in the channel region 107; and 3) thereafter removing the sacrificial encapsulating layer 112, not only serve to significantly increase general processing complexity, but they may reduce overall product yield in those instances when the etch removal step 133 is not properly performed. Accordingly, there is a need to implement new process design strategies to address the manufacturing issues associated with incorporating stress-induced performance enhancement schemes, such as stress memorization techniques, in the processing of modern integrated circuit elements. The present disclosure relates to methods for avoiding, or at least reducing the effects of, one or more of the problems identified above.

### SUMMARY OF THE DISCLOSURE

The following presents a simplified summary of the present disclosure in order to provide a basic understanding of some aspects disclosed herein. This summary is not an exhaustive overview of the disclosure, nor is it intended to identify key or critical elements of the subject matter disclosed here. Its sole purpose is to present some concepts in a simplified form as a prelude to the more detailed description that is discussed later.

Generally, the subject matter disclosed herein relates to sophisticated semiconductor devices and methods for forming the same, wherein stress memorization techniques are used to enhance the performance of MOS transistor elements. One illustrative embodiment disclosed herein includes a method for forming a gate electrode above a channel region of a semiconductor device, wherein the channel region is formed in an active region of a semiconductor substrate. The method further includes forming a dielectric encapsulating layer in direct contact with the gate electrode, and performing a heat treatment process to induce a residual stress in the channel region.

Another illustrative method disclosed by the present subject matter includes forming a gate electrode of an NMOS transistor element above an active region of a semiconductor device, and forming a dielectric encapsulating layer in direct contact with at least an upper surface and opposing sidewall surfaces of the gate electrode. The method also includes performing a rapid thermal annealing process to induce a residual lateral tensile stress in a channel region of the NMOS transistor element.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate a process flow of an illustrative prior art method for forming contact elements in a semiconductor device; and

FIGS. 2a-2k schematically illustrate a process flow of an illustrative embodiment of the subject matter disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the present subject matter are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein provides manufacturing techniques and semiconductor devices in which a stress memorization technique may be used to induce a residual stress in the channel region of an MOS transistor, thereby enhancing overall device performance. Due to the additional manufacturing steps necessary for the integration schemes that presently incorporate stress memorization techniques to improve transistor performance, processing complexity is significantly increased, leading directly to increased production costs and the potential for a commensurate reduction in production yield. The present disclosure contemplates a process flow wherein the device manufacturing steps associated with inducing a performance-enhancing residual stress do not significantly deviate from the steps that might be performed in conventional process flows. Accordingly, in some illustrative embodiments, the presently disclosed subject matter reflects stress memorization techniques wherein the encapsulating layer may not be removed after performing the heat treatment process that induces the “memorized” residual stress in the channel region of a highly sophisticated transistor element—i.e., the encapsulating layer remains in place during subsequent processing steps.

The subject matter of the present disclosure also addresses the deleterious effects that may result from the presence of any intermediate material layers and/or elements between the encapsulating layer and channel region, or the presence of metal gate materials in the gate electrode, might have on the ability of the encapsulating layer to facilitate the development of a “memorized” residual stress below the gate electrode/gate dielectric layer interface. To that end, the methods disclosed herein contemplate, in some illustrative embodiments, forming the encapsulating layer as close as possible to the gate electrode/gate dielectric layer interface—i.e., without any intervening layers and/or elements.

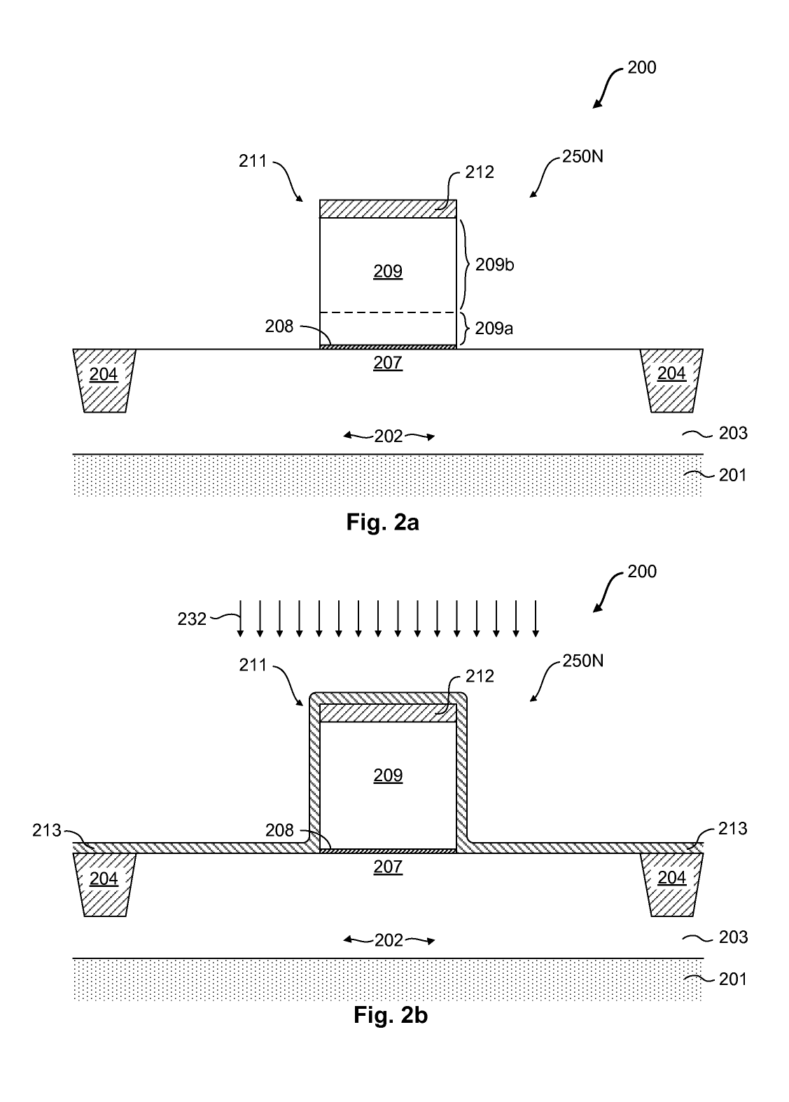

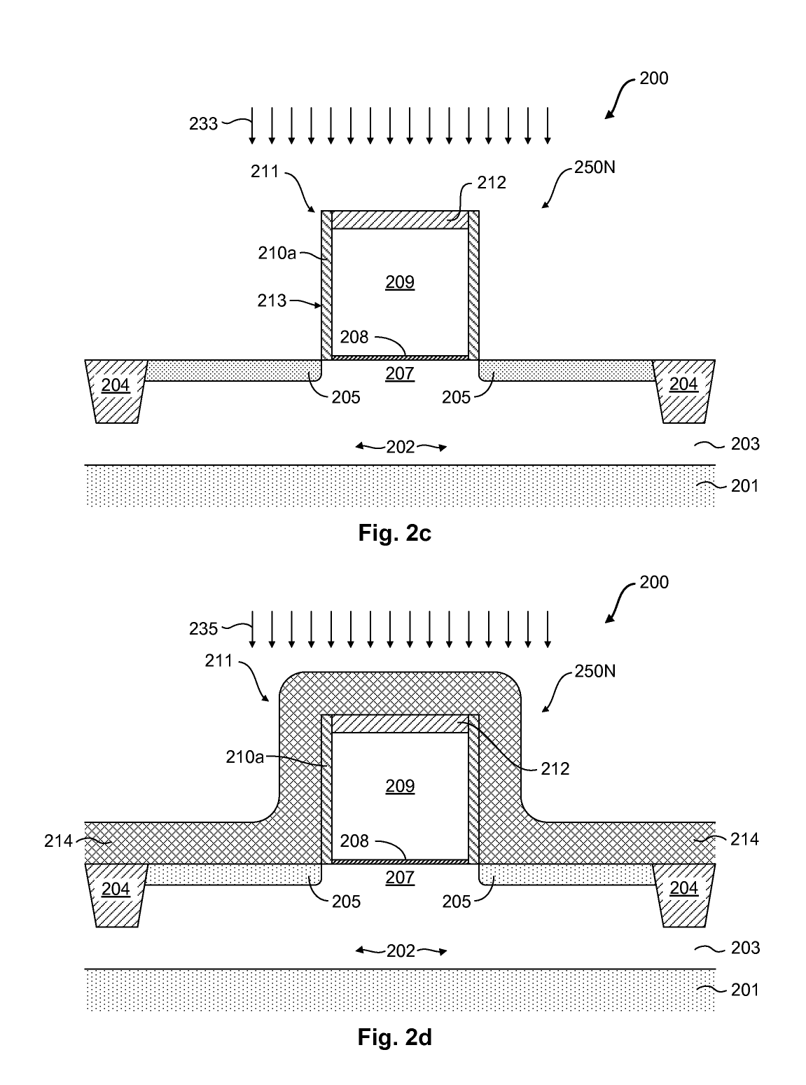

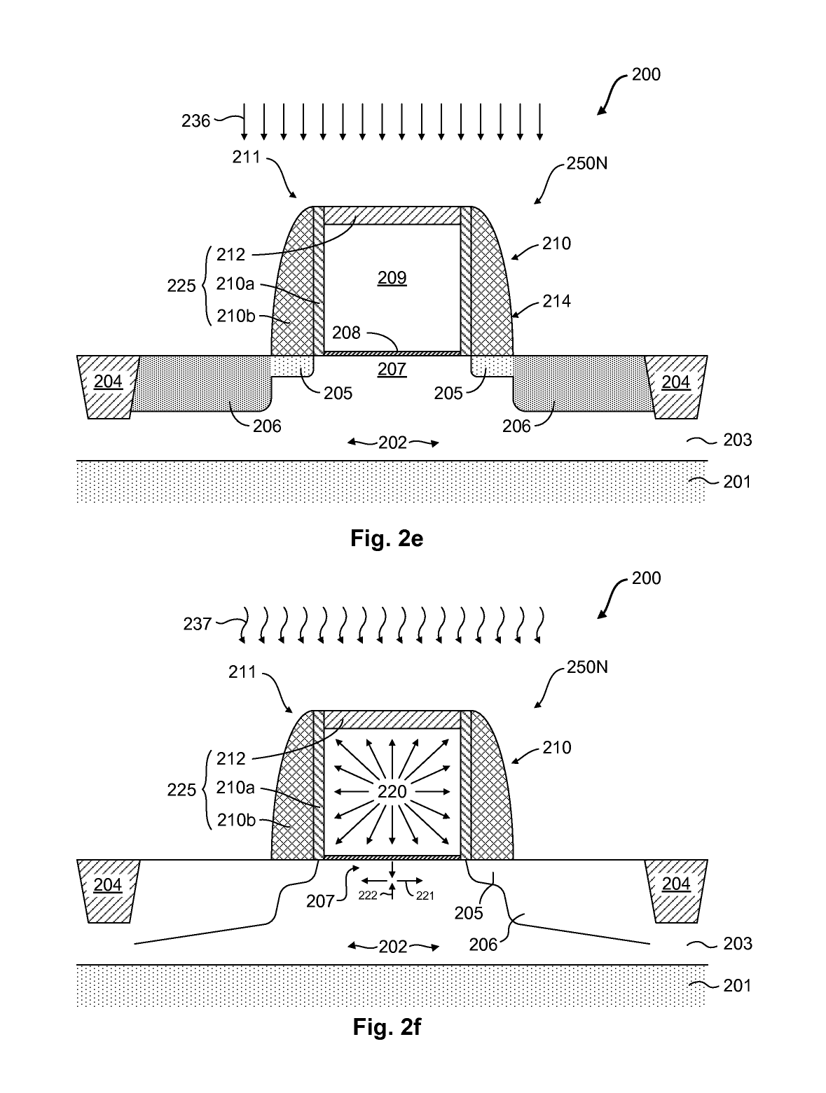

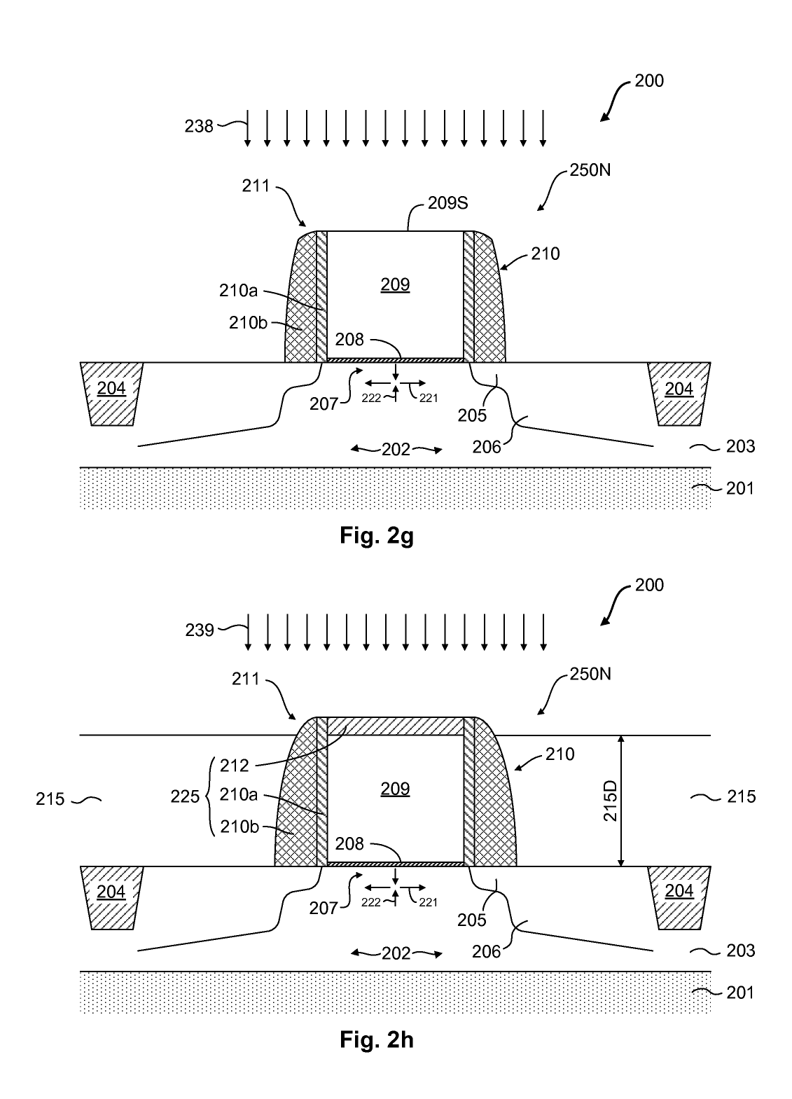

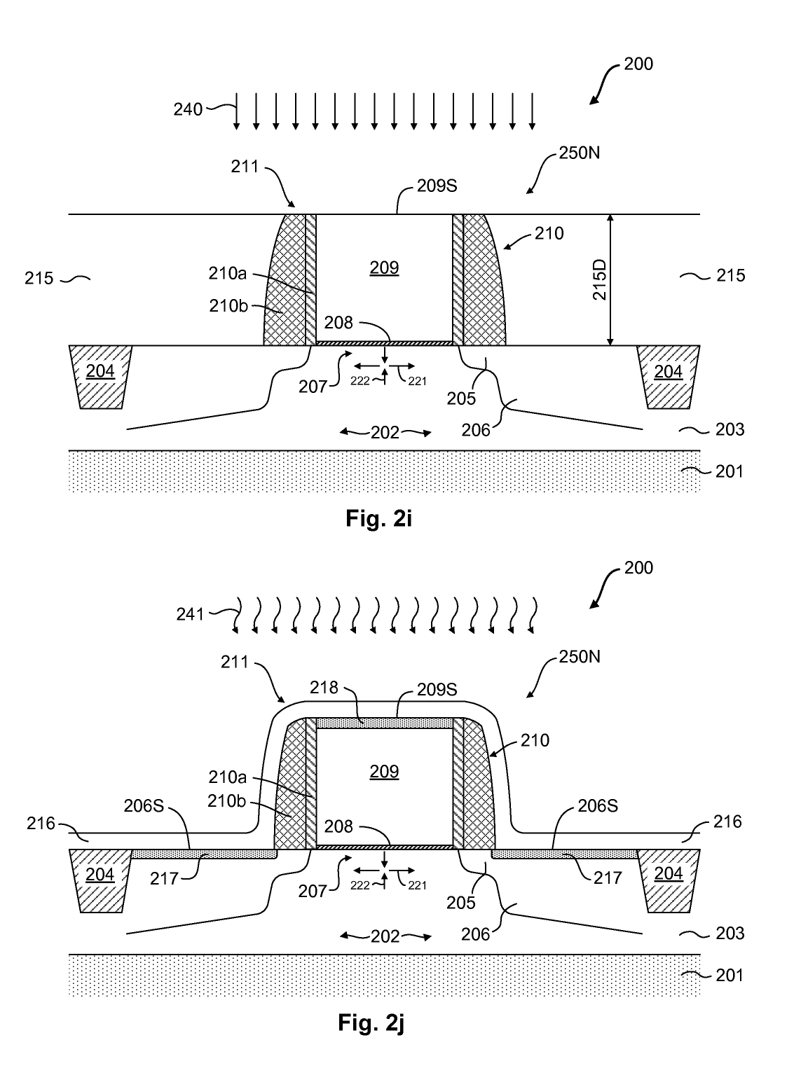

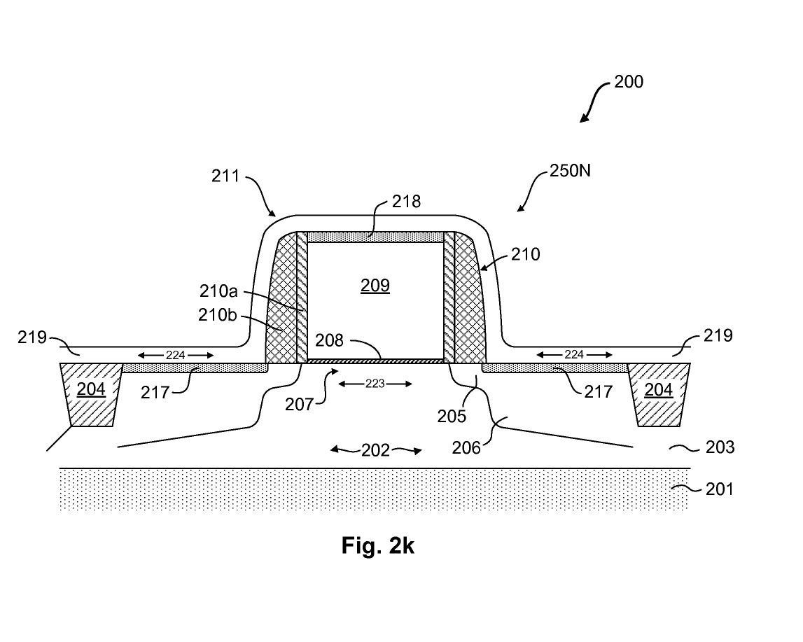

FIG. 2a shows a schematic cross-sectional view of an illustrative semiconductor device 200 of the present disclosure that corresponds to a manufacturing stage wherein initial gate electrode patterning steps have been substantially completed. The semiconductor device 200 of FIG. 2a may include, in some embodiments, a substrate 201, which may be a silicon substrate or any other appropriate substrate which comprises a semiconductor layer 203, such as a silicon-based layer, or any other appropriate semiconductor material. The semiconductor layer 203 may, in some illustrative embodiments, comprise an active region 202 in and above which may be formed an illustrative N-channel (NMOS) transistor element 250N. In some embodiments, the active region 202 may be defined by a shallow trench isolation structures 204, as may commonly be used in devices of this type. The active region 202 may comprise a suitable concentration of P-type dopant material so as to provide the proper device conductivity, such as boron and the like.

It should be appreciated that the semiconductor layer 203, even if provided as a silicon-based layer, may include other materials, such as germanium, carbon and the like, in addition to the appropriate dopant species for establishing the requisite conductivity type in the active region 202, as discussed above. Furthermore, in some illustrative embodiments, the semiconductor layer 203 may be formed on or be part of a substantially crystalline substrate material, i.e., bulk silicon material, while in other cases specific device regions of the semiconductor device 200 may be formed on the basis of a silicon-on-insulator (SOI) architecture, in which a buried insulating layer (not shown) may be provided below the semiconductor layer 203. Thus, the present invention should be understood to be applicable to a transistor element formed in and above any type of semiconductor layer 203, irrespective of the surrounding structure or how the semiconductor layer 203 was made.

The illustrative NMOS transistor element 250N may comprise a gate electrode structure 211, which, in the manufacturing stage shown in FIG. 2a, may further comprise a gate electrode 209 formed above a gate dielectric layer 208, which separates the gate electrode 209 from a channel region 207. Furthermore, in some embodiments, a dielectric cap layer 212 may also be formed above the gate electrode 209. In some embodiments of the present disclosure, the dielectric cap layer 212 may serve as an upper portion of an encapsulating material layer that may, during a subsequently performed heat treatment process, facilitate the introduction of a “memorized” residual stress in the channel region 207 of the illustrative NMOS transistor element 205N, as will later be discussed in further detail. In one illustrative embodiment, the material of the dielectric cap layer 212 may comprise, for example, silicon nitride, which in some instances may provide a greater stress-inducing benefit to the overall stress memorization techniques disclosed herein, and which will also be discussed below.

In some illustrative embodiments of the present disclosure, the process strategy may comprise a full metal gate, and/or a gate-first HK/MG integration scheme. In such illustrative embodiments, the material of the gate electrode 209 may comprise a suitable metal gate material such as titanium nitride (TiN), titanium aluminum nitride (TiAlN), titanium silicon nitride (TiSiN) and the like. Furthermore, for example, when a metal gate electrode is contemplated, the gate dielectric layer 208 may comprise an appropriately selected high-k gate dielectric material (i.e., a dielectric material having a dielectric constant of approximately 10 or greater), such as tantalum oxide (Ta₂O₅), strontium titanium oxide (SrTiO₃), hafnium oxide (HfO₂), hafnium silicon oxide (HfSiO), zirconium oxide (ZrO₂) and the like.

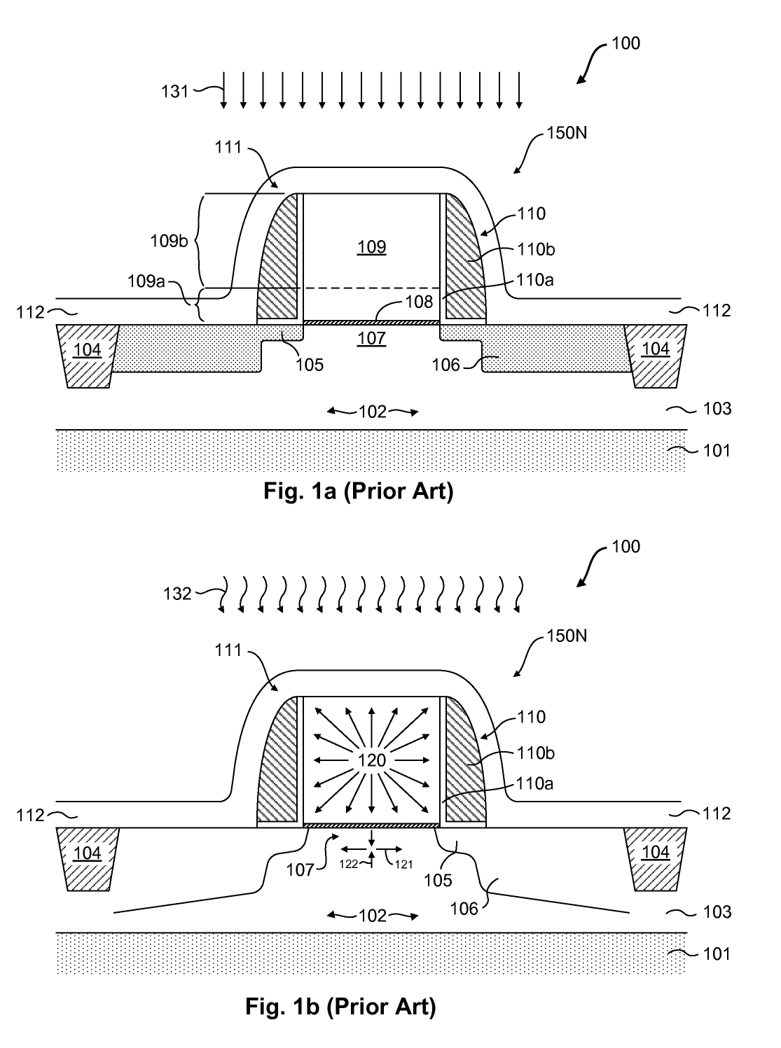

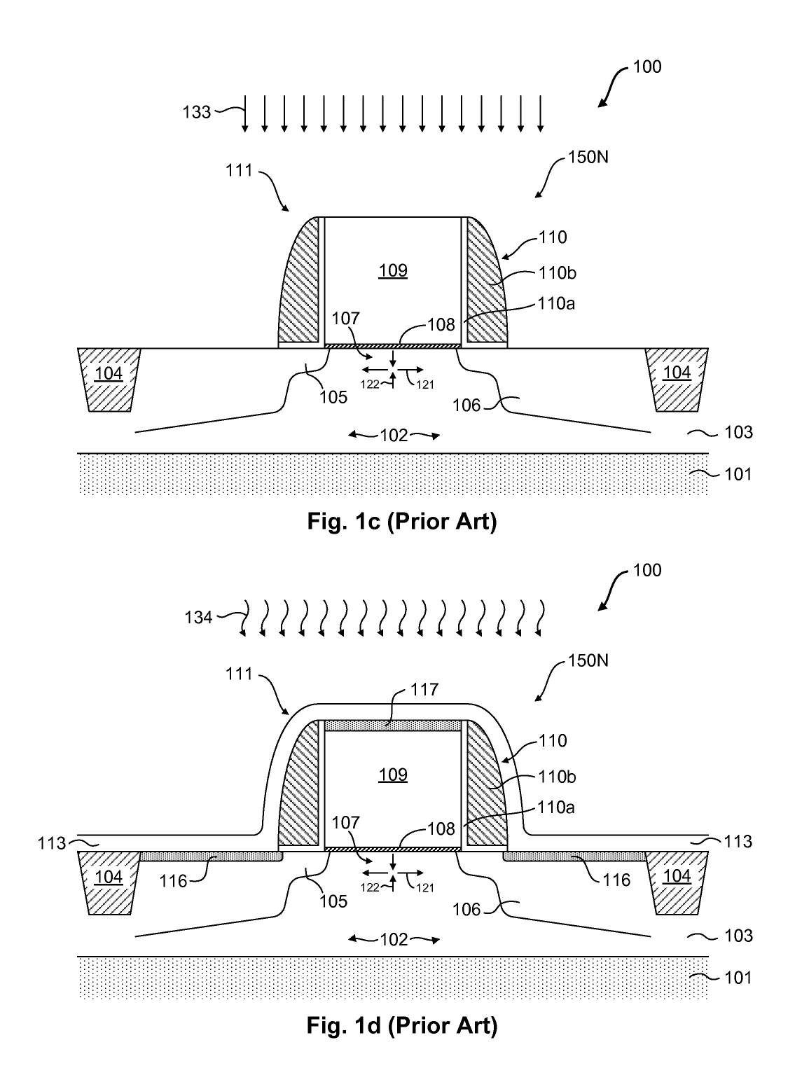

In other illustrative embodiments, the desired process strategy may include a conventional gate electrode stack integration scheme, wherein the material of the gate electrode 209 may comprise, for example, a polysilicon material, and the gate dielectric layer 207 may be comprised of a suitable material such as silicon dioxide, silicon oxynitride, a high-k material, and the like. In some integration schemes, the gate electrode 209 utilized in the semiconductor device 200 may be comprised of multiple layers, e.g., a first layer 209a of metal gate material formed above a high-k gate dielectric material 208, followed by a second layer 209b of a polysilicon material, as described above with respect to FIG. 1a above.

In some embodiments of the present disclosure, the illustrative semiconductor device 200 of FIG. 2a may be formed as follows. After forming the trench isolation structures 204 based on sophisticated patterning, etching, deposition and/or planarizing techniques well know in the art, a layer of gate dielectric material 208 may be formed above the semiconductor layer 203. In some illustrative embodiments, and depending on the device requirements and the specific material type, the gate dielectric layer 208 may be deposited to the appropriate thickness using a suitable deposition process designed for forming a thin, conformal material layer. For example, a thin layer of silicon dioxide, silicon oxynitride, and/or high-k dielectric materials may readily be deposited above the semiconductor layer 203 based on ALD, PECVD, and the like. In other embodiments, the gate dielectric layer 208 may be formed by performing an oxidizing and/or oxynitriding process, wherein the surface of the semiconductor layer 203 may be exposed to a suitable oxygen-containing or oxygen/nitrogen-containing ambient, such as plasma ambient, and the like.

A layer of gate electrode material 209 may then be deposited above the gate dielectric layer 208. Depending on the desired integration scheme, the layer of gate electrode material 209 may comprise, in some illustrative embodiments, a polysilicon material. In other embodiments, the layer of gate electrode material 209 may comprise a metal gate material, such as titanium nitride, and the like. In yet another embodiment, the layer of gate electrode material 209 may comprise a first layer 209a of a metal gate material, followed by a second layer 209b of polysilicon.

Next, in one illustrative embodiment, the dielectric cap layer 212 may be deposited above the layer of gate electrode material 209. Generally, in one example, the dielectric cap layer 212 should be thick enough to provide adequate strength to an overall encapsulating layer during a later-performed stress memorization heat treatment process, as will be described in detail below. For example, in some illustrative embodiments of the present disclosure, the thickness of the dielectric cap layer 212 may be in the range of 30-40 nm or even greater. Moreover, in certain embodiments, the dielectric cap layer 212 may be comprised of a material having overall properties that, in addition to the material thickness, further contributes to providing the above-noted requisite strength during subsequent stress-memorization steps. For example, in one illustrative embodiment, the dielectric cap layer may comprise silicon nitride, which as noted previously has a greater strength and higher hardness than, for example, polysilicon. Thereafter, the gate electrode structure 211 of FIG. 2a may be patterned based upon sophisticated lithography and anisotropic etch techniques well known in the art so as to provide the desired gate electrode dimensions, i.e., gate length and gate width.

FIG. 2b depicts the illustrative semiconductor device 200 of FIG. 2a in a further advanced manufacturing stage, wherein a first dielectric material layer 213 may be formed above the illustrative NMOS transistor element 205 so as to fully encapsulate the gate electrode 209. The first dielectric material layer 213 may, in some illustrative embodiments, be formed on the basis of an appropriately designed conformal deposition process, such as ALD, LPCVD, and the like. Depending on the overall device requirements, the thickness of the first dielectric material layer 213 may be adjusted as necessary so as to define the extent of subsequently formed source/drain extension regions, wherein a relatively thin layer may lead provide a shorter channel length, thus leading to better transistor performance. For example, in some illustrative embodiments, the first dielectric material layer 213 may have a thickness in the ranges of approximately 2-5 nm, whereas in one embodiment the thickness of the first dielectric material layer 213 may be approximately 3 nm. In other specific embodiments, however, the dielectric material layer may not even be formed, again depending on device requirements.

In other illustrative embodiments of the present disclosure, the first dielectric material layer 213 may be relatively thick, thereby providing additional strength and overall stiffness to an encapsulating layer during a subsequently performed stress memorization heat treatment process, as will be discussed below. For example, in some illustrative embodiments, a thickness of the first dielectric material layer 213 may be on the order of approximately 10-20 nm, whereas in one particularly illustrative embodiment the thickness of the first dielectric material layer 213 may be approximately 15 nm. However, it should be noted that a thicker first dielectric material layer 213 may, depending upon subsequent processing, also result in a somewhat greater channel length, thereby tending to slightly decrease the overall transistor performance characteristics. Accordingly, there may be some degree of device design trade-offs associated with the thickness of the first dielectric material 213, wherein a thinner layer may provide better performance via a shorter channel length, versus a thicker layer, which may better help to provide performance enhancement through a “memorized” stress field in the channel region 207.

The first dielectric material layer 213 may be comprised of any appropriate material that may be employed to impart a desired stress to the channel region 207. For example, in one illustrative embodiment of the presently disclosed subject matter, the first dielectric material layer 213 may comprise silicon nitride. As previously discussed with respect to FIGS. 1a-1b above, the greater material strength and higher hardness of silicon nitride material when compared to that of the materials comprising the gate electrode 209 may in some illustrative embodiments contribute to a higher level of induced stress in the channel region 207 of the illustrative NMOS transistor element 250N resulting from the stress memorization techniques disclosed herein.

As shown in FIG. 2b, an etch process 232 may be performed to remove horizontal portions of the first dielectric material layer 213 from above the active region 202 of the illustrative NMOS transistor element 250N. The etch process 232 may comprise, for example, an anisotropic etch process, such as a reactive ion etch (RIE) and the like. Additionally, at least some amount of the horizontal portion of the first dielectric material layer 213 that has been formed above the dielectric cap layer 212 may also be removed during the etch process 232. In some illustrative embodiments, some portion of the thickness of the first dielectric material layer 213 may remain above the dielectric cap layer 212. In other embodiments, the entire thickness of the first dielectric material layer 213 above the dielectric cap layer 212 may be removed during the etch process 232, and perhaps even with some amount of the cap layer 212. However, due to the anisotropic nature of the etch process 232, the vertical portions of the dielectric material layer formed on the sidewalls of the gate electrode 209—i.e., offset spacers 210a (see FIG. 2c)—will remain substantially in place after completion of the etch process 232.

FIG. 2c shows the illustrative semiconductor device 200 of FIG. 2b in yet a further stage of manufacturing, after completion of the etch process 232, in which the entirety of the first dielectric material layer 213 has been removed from above the dielectric cap layer 212. As depicted in FIG. 2c, for an illustrative NMOS transistor element 250N, a first dopant implantation process 233 may be performed so as introduce N-type dopant materials, such as phosphorous or arsenic, and the like into the active region 202 adjacent to the sidewall spacers 210a, thereby forming shallow, lightly-doped source/drain extension regions 205, which are separated by the channel region 207. In some illustrative embodiments, the first dopant implantation process 233 may comprise, for example, an ion implantation process based on appropriately designed process parameters for obtaining the required dopant concentration and depth. As noted with respect to FIG. 2b above, the lateral extent of the source/drain extension regions 205 may be set by adjusting the as-deposited thickness of the first dielectric material layer 213, which, after performing the etch process 232 (see FIG. 2b) may then comprise an offset spacer element 210a. Additionally, and depending on specific device requirements, a halo implantation process (not shown) may be performed in some illustrative embodiments prior to performing the first dopant implantation process 233 so as to create halo implantation regions (not shown).

FIG. 2d depicts the semiconductor device 200 in a further illustrative manufacturing stage, wherein a second dielectric material layer 214 may be formed above the illustrative NMOS transistor 250N. As shown in FIG. 2d, the second dielectric material layer 214 covers the active area 202 of the illustrative NMOS transistor 250N, the offset spacer elements 210a, and the dielectric cap layer 212 formed above the gate electrode 209. Additionally, the second dielectric material layer 214 may also cover including any horizontal portion of the first dielectric material layer 213 formed above the dielectric cap layer 212 that may remain after performing the anisotropic etch process 232. The second dielectric material layer 214 may be formed, in some illustrative embodiments, on the basis of a suitable material deposition process, such as a chemical vapor deposition (CVD) process, and the like. Furthermore, the thickness of the second dielectric material layer 214 may be adjusted as required so as to define the width of subsequently formed sidewall spacer elements 210b (see FIG. 2e) and the corresponding extent of deep, heavily-doped source/drain regions 206 (see FIG. 2e) formed in the active region 202, as will be described in further detail below.

As shown in FIG. 2d, an etch process 235 may then be performed on the semiconductor device 200 so as to remove horizontal portions of the second dielectric material layer 214 covering the active region 202, thereby forming appropriately sized sidewall spacer elements 210b (see FIG. 2e). In some embodiments, the etch process 235 may comprise a dry anisotropic etch process that exhibits etch selectivity to the material comprising the second dielectric material layer 214, such as a plasma assisted etch process, RIE process, and the like. As previously noted with respect to the first dielectric material layer 213, at least some amount of the horizontal portion of the second dielectric material layer 214 that has been formed above the dielectric cap layer 212, to the extent it was not previously removed, may also be removed during the etch process 235. In some illustrative embodiments, some portion of the thickness of the second dielectric material layer 214 may remain above the dielectric cap layer 212, whereas in other embodiments, the entire thickness of the second dielectric material layer 214 formed above the dielectric cap layer 212 may be removed during the etch process 235.

The first dielectric material layer 214 may comprise any appropriate material that may be employed to impart the desired stress to the channel region 207. For example, in one illustrative embodiment, the second dielectric material layer 214—and correspondingly, the sidewall spacer elements 210b—may comprise silicon nitride. As previously discussed with respect to the dielectric cap layer 212 and the first dielectric material layer 213, the relatively greater strength and higher hardness of silicon nitride material when compared to that of the materials comprising the gate electrode 209 may induce a higher level of residual stress in the channel region 207 of the illustrative NMOS transistor element 250N based on the stress memorization techniques disclosed herein.

FIG. 2e illustrates the semiconductor device 200 of FIG. 2d after completion of the anisotropic etch process 235 and subsequent formation of the sidewall spacer elements 210b. As shown in FIG. 2e, the illustrative NMOS transistor element 250N may now comprise sidewall spacer structures 210 disposed on either side of the gate electrode 209, each of which may include an offset spacer element 210a and sidewall spacer element 210b. Accordingly, the gate electrode structure 211 may now be fully encapsulated—i.e., surrounded on three sides—by an encapsulating layer 225, which in the embodiment illustrated in FIG. 2e comprises the sidewall spacer structures 210 formed on opposite lateral sides of the gate electrode 209 and the dielectric cap layer 212 formed thereabove. As discussed above with respect to the individual material layers 212, 213 and 214 comprising each of the various “encapsulating” subcomponents 210a, 210b and 212, the encapsulating layer 225 may comprise, in some illustrative embodiments, silicon nitride.

As further shown in FIG. 2e, a second dopant implantation 236 may be performed so as introduce additional N-type dopant materials, such as phosphorous or arsenic, and the like into the active region 202 adjacent to the sidewall spacer structures 210 formed on the sidewalls of the gate electrode 209, thereby forming deep, heavily-doped source/drain extension regions 206. In some embodiments, the second dopant implantation process 236 may comprise, an ion implantation process based on appropriately designed process parameters for obtaining the required dopant concentration and depth. As noted with respect to FIG. 2d above, the lateral extent of the source/drain regions 206 may be set based upon the as-deposited thickness of the second dielectric material layer 214 and the anisotropic etch process 235 used to form the sidewall spacer elements 210b.

FIG. 2f illustrates the semiconductor device 200 of FIG. 2e in yet a further advanced manufacturing stage, wherein a heat treatment process 237 may be performed. Depending on the device requirements and overall process design strategies, the heat treatment process 237 may be designed, in some illustrative embodiments, to accomplish several functions. For example, the heat treatment process 237 may be performed to correct crystalline damage that may have been induced in the source/drain regions 206 and extension regions 205 during the dopant implantation processes 233 (see FIG. 2c) and 236 (see FIG. 2e), as well as to activate the N-type dopants implanted during the processes 233, 236. Furthermore, the heat treatment process 237 may also be performed so as to simultaneously induce a residual stress in the channel region 207 of the illustrative NMOS transistor element 250N. More specifically, the heat treatment process 237 may be designed to cause: 1) a thermal expansion of the material comprising the gate electrode 209 (as shown by arrows 220) relative to the encapsulating layer 225 surrounding the gate electrode 209 on three sides; 2) a corresponding plastic deformation of the gate electrode 209, which may thereby be forced to expand downward toward the gate dielectric layer 208/channel region 207 interface; and 3) the subsequent introduction of a residual stress field in the channel region 207 below the gate dielectric layer 208, which comprises both a lateral (i.e., approximately parallel to the gate dielectric layer 208) tensile stress component 221 and a vertical (i.e., approximately perpendicular to the gate dielectric layer 208) compressive stress component 222.

In certain illustrative embodiments, the heat treatment process 237 may be, for example, a rapid thermal annealing (RTA) process, and which may in some instances be performed at approximately 1000°-1100° C. for a total duration of approximately 10 seconds. In one specific embodiment, the heat treatment process 237 may be an RTA process performed at a target temperature of approximately 1050° C., wherein the device 200 may be held at the 1050° C. target temperature for approximately 2 seconds.

FIG. 2g shows the illustrative semiconductor device 200 of FIG. 2f in a further manufacturing stage, wherein the device 200 may be exposed to an etch process 238 designed to remove the dielectric cap layer 212 and thereby expose the upper surface 209S of the gate electrode 209. In some embodiments, the etch process 238 may be, for example, a suitable dry anisotropic etch process, such as a plasma assisted etch process, an RIE process, and the like. As shown in FIG. 2g, the height and width of the sidewall spacer structures 210 may also be reduced during the etch process 238. Thereafter, further processing of the semiconductor device 200 may proceed in accordance with the subsequent conventional integration schemes used for highly sophisticated integrated circuit devices, such as formation of metal silicides in the contact regions of the illustrative NMOS transistor element 250N, as later shown in FIG. 2j and described below.

FIG. 2h illustrates an optional embodiment of the presently disclosed subject matter for removing the dielectric cap layer 212 and exposing the upper surface 209S of the gate electrode 209. As shown in FIG. 2h, a substantially non-conformal material layer 215 may be formed above the semiconductor device 200 based on a material deposition process 239. In some illustrative embodiments, the deposition process 239, which may in some instances be referred to as a wet-gap fill process, may comprise, for example, a spin-on glass deposition process and the like, wherein the non-conformal material layer 215 may “fill the gaps” between the gate electrode structure 210 of the illustrative NMOS transistor 250N and any adjacent device structures (not shown). The non-conformal material layer 215 may, for example, be deposited to a total depth 215D that may be substantially equal to the desired final height of the gate electrode 209. In the embodiment illustrated in FIG. 2h, the total depth 215D may be substantially the same as the location of the interface between the gate electrode 209 and the dielectric cap layer 212. In some embodiments, the material of the non-conformal material layer 215 may exhibit etch selectivity to the dielectric cap layer 212 and the sidewall spacer structures 210—i.e., to the subcomponents of the encapsulating layer 225—thereby facilitating: 1) the selective removal of the cap layer 212 by a suitable etch process; and 2) the subsequent selective etch removal of the non-conformal material layer 215 from above the semiconductor device 200 without inducing significant etch-related damage to the sidewall spacer structures 210. For example, in those illustrative embodiments of the present disclosure wherein the encapsulating layer 225 comprises silicon nitride, the non-conformal material layer 215 may comprise silicon dioxide.

FIG. 2i illustrates the semiconductor device 200 of FIG. 2h during an etch process 240, thereby removing the dielectric cap layer 212 from above the gate electrode 209 and exposing the upper surface 209S of the gate electrode 209. The etch process 240 may, in some illustrative embodiments, be an isotropic wet etch process suitably designed to selectively remove the dielectric cap layer 212 relative to the non-conformal material layer 215. For example, in those embodiments wherein the dielectric cap layer 212 comprises silicon nitride and the non-conformal material layer 215 comprises silicon dioxide, the etch process 240 may comprise a hot phosphoric acid etch process and the like. As shown in FIG. 2i, an upper portion of the sidewall spacer structures 210 may also be removed during the etch process 240, however, unlike the dry anisotropic etch process 238 illustrated in FIG. 2g and discussed above, the overall width of the sidewall spacer structures 210 may not be affected.

FIG. 2j shows the illustrative semiconductor device 200 of FIG. 2g in yet a further manufacturing stage, wherein metal silicide contact regions 217 may be formed in the upper portion of the source/drain regions 206 of the illustrative NMOS transistor 250N, and metal silicide region 216 may be formed in the upper portion of the gate electrode 209. As shown in FIG. 2j, a refractory metal layer 216, such as, nickel or cobalt, and the like, may be formed above and in contact with the silicon-containing regions of the illustrative NMOS transistor element 250N where formation of metal silicide regions may be appropriate, depending on the overall device requirements and desired process sequence. For example, the refractory metal layer 216 may be formed above the upper surfaces 206S of the source/drain regions 206, and in those embodiments of the present disclosure wherein the gate electrode 209 comprises a polysilicon material, the refractory metal layer 216 may also be formed above the upper surface 209S of the gate electrode 209. Thereafter, a heat treatment 241 may be performed so to induce a chemical reaction between the refractory metal layer 216 and the silicon material comprising the source/drain regions 206 and/or the gate electrode 209. In some illustrative embodiments, the heat treatment 241 may comprise a thermal annealing sequence, recipes for which are well-known in the art, and which may depend on the specific type of material comprising the refractory metal layer 216. Thereafter, unreacted portions of the refractory metal layer 216 are removed in accordance with a suitably designed selective wet etch process, recipes of which are also well known to those having ordinary skill in the art.

It should be noted that, in view of the process techniques disclosed herein, the presence of contact region defects in the metal silicide regions 217 and 218 may be diminished when compared to the prior art process illustrated in FIGS. 1a-1d and described above. Since an encapsulating material layer, such as the sacrificial silicon nitride encapsulating layer 112 shown in FIG. 1b, is not deposited above the semiconductor device 200 and left in place during a heat treatment process designed to induce a residual stress in the channel region, and then subsequently removed, the possibility that some residual portions of the encapsulating layer might remain in contact with the silicon-containing regions of the device 200 even after the subsequent removal step may be significantly reduced, thereby also reducing the likelihood that silicide region defects may occur.

FIG. 2k illustrates the semiconductor device 200 of FIG. 2j in a further advanced manufacturing stage. As shown in FIG. 2k, a dielectric overlayer 219 may be deposited above the illustrative NMOS transistor element 250N. The dielectric overlayer 219 may comprise, in some illustrative embodiments, an inherent stress 224, which may, in combination with the lateral tensile stress 221 induced during the stress memorization steps described above (see, i.e., FIG. 2f), create an adjusted lateral tensile stress 223 in the channel region 207 of the illustrative NMOS transistor element 250N. In some illustrative embodiments, the inherent stress 224 may be a tensile stress, thereby increasing the level of the adjusted lateral tensile stress 223, and subsequently further enhancing the mobility of electrons in the channel region 207. In other embodiments, the inherent stress 224 of the dielectric overlayer 219 may comprise a compressive stress, such that the resulting adjusted lateral tensile stress 223—and subsequent electron mobility in the channel region 207—may be decreased, as some device requirements may require.

The dielectric overlayer 219 may comprise, in some embodiments, an appropriately stressed dielectric material such as silicon nitride, silicon dioxide, or silicon oxynitride, and the like. Furthermore, depending on the overall process strategy, as well as the desired type and level of inherent stress 224, the deposition parameters used for forming the dielectric overlayer 219 may be adjusted as required, based upon recipes and techniques known in the art. The dielectric overlayer 219 may thereafter be used, in some illustrative embodiments, as an etch stop layer to facilitate forming contact via openings so as to expose the metal silicide regions 217, 218, prior to forming contact elements for metallization layers formed above the illustrative NMOS transistor element 250N.

In view of the stress memorization techniques disclosed herein, the residual stress levels induced in the channel region of NMOS transistor elements may be significantly enhanced in comparison to the prior methods presently being practiced. Generally, this enhanced level of residual stress may be accomplished by utilizing an encapsulating layer that may be formed as close as possible to the gate electrode and channel region of the device, i.e., substantially without any, or a limited number and quantity of, intervening material layers or other elements. Moreover, integration of the encapsulating layer into the conventional integrated circuit processing scheme—i.e., wherein the conventionally formed sidewall spacer structures and cap layer make up the encapsulating layer—permits the encapsulating layer components to remain in place after completion of the stress memorization steps described herein have been completed, thereby significantly reducing overall process complexity.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a gate electrode above a channel region of a semiconductor device, wherein said channel region is formed in an active region of a semiconductor substrate;
forming a silicon nitride encapsulating layer in direct contact with said gate electrode, said silicon nitride encapsulating layer comprising a silicon nitride cap layer portion in direct contact with an upper surface of said gate electrode and silicon nitride sidewall portions in direct contact with opposing sidewall surfaces of said gate electrode; and
performing a heat treatment process in the presence of said silicon nitride encapsulating layer to induce a residual stress in said channel region.

2. The method of claim 1, wherein forming said silicon nitride encapsulating layer comprises:
forming a silicon nitride cap layer on an upper surface of a layer of gate electrode material and performing a patterning process to form said gate electrode and said silicon nitride cap layer portion;
forming at least one layer of silicon nitride spacer material above said silicon nitride cap layer portion and on said opposing sidewall surfaces of said gate electrode; and
forming silicon nitride sidewall spacer structures on said opposing sidewall surfaces of said gate electrode from said at least one layer of silicon nitride spacer material, said silicon nitride sidewall portions comprising said silicon nitride sidewall spacer structures.

3. The method of claim 2, wherein forming said silicon nitride sidewall spacer structures comprises forming a silicon nitride offset spacer element on each of said opposing sidewall surfaces of said gate electrode, and forming a silicon nitride sidewall spacer element on each of said silicon nitride offset spacer elements.

4. The method of claim 1, wherein performing said heat treatment process comprises performing a rapid thermal annealing process.

5. The method of claim 4, wherein performing said rapid thermal annealing process comprises heating said semiconductor device to a temperature between approximately 1000° C. and 1100° C.

6. The method of claim 5, wherein performing said rapid thermal annealing process comprises heating said semiconductor device to a temperature of approximately 1050° C. for approximately 2 seconds.

7. (canceled)

8. (canceled)

9. The method of claim 3, wherein forming said silicon nitride offset spacer elements comprises depositing a first silicon nitride material layer above said semiconductor device, and forming said silicon nitride sidewall spacer elements comprises forming a second silicon nitride material layer above said semiconductor device and on at least a portion of said first silicon nitride material layer.

10. The method of claim 1, wherein forming said silicon nitride encapsulating layer comprises performing at least one etch process.

11. The method of claim 2, wherein forming said silicon nitride sidewall spacer structures comprises removing horizontal portions of said at least one silicon nitride material layer from above said active region of said semiconductor device.

12. The method of claim 9, wherein forming at least one of said offset spacer elements and said sidewall spacer elements comprises removing horizontal portions of at least one of said first and second silicon nitride material layers from above said active region of said semiconductor device.

13. A method, comprising:
forming a material stack above an active region of a semiconductor device, said material stack comprising a layer of gate electrode material and a layer of silicon nitride cap material formed on an upper surface of said layer of gate electrode material;
patterning said material stack to form a gate electrode of an NMOS transistor element, said gate electrode having a silicon nitride cap layer on and in direct contact with an upper surface thereof;
forming a silicon nitride material layer in direct contact with at least an upper surface of said silicon nitride cap layer and opposing sidewall surfaces of said gate electrode;
forming a silicon nitride encapsulating layer from said silicon nitride cap layer and said silicon nitride material layer; and
performing a rapid thermal annealing process in the presence of said silicon nitride encapsulating layer to induce a residual lateral tensile stress in a channel region of said NMOS transistor element.

14. (canceled)

15. The method of claim 13, wherein forming said silicon nitride encapsulating layer comprises forming silicon nitride sidewall spacer structures on said opposing sidewall surfaces of said gate electrode.

16. The method of claim 15, further comprising forming source and drain regions adjacent said channel region after forming said silicon nitride encapsulating layer, wherein forming said source and drain regions comprises performing a dopant implantation process to implant N-type dopants in said active region.

17. The method of claim 15, wherein forming said dielectric silicon nitride sidewall spacer structures comprises:
forming a first layer of said silicon nitride material layer above said NMOS transistor element;
performing a first anisotropic etch process to remove horizontal portions of said first layer of said silicon nitride material layer from above said active region and thereby form first spacers on said opposing sidewalls of said gate electrode;
forming a second layer of said silicon nitride material layer above said NMOS transistor element, wherein at least a portion of said second layer of said nitride material layer is formed on said first spacers; and
performing a second anisotropic etch process to remove horizontal portions of said second layer of said silicon nitride material layer from above said active region and thereby form second spacers on said first spacers.

18. The method of claim 17, further comprising forming source and drain extension regions adjacent said channel region prior to forming said second layer of said silicon nitride material layer, wherein forming said source and drain extension regions comprises performing a dopant implantation process to implant N-type dopants in said active region.

19. The method of claim 16, wherein performing said rapid thermal annealing process comprises activating said N-type dopants.

20. The method of claim 13, further comprising selectively removing a first portion of said silicon nitride encapsulating layer from above said upper surface of said gate electrode after inducing said residual lateral tensile stress.

21. The method of claim 20, wherein selectively removing said first portion of said silicon nitride encapsulating layer comprises leaving second portions of said silicon nitride encapsulating layer at least on said opposing sidewall surfaces of said gate electrode.

22. The method of claim 13, further comprising forming a material layer comprising an intrinsic stress above said NMOS transistor element after inducing said residual lateral tensile stress.
